(19) United States
(12) Patent Application Publication
(10) Pub. No.: US 2024/0331928 A1
(43) Pub. Date: Oct. 3, 2024

(54) INDUCTOR-TYPE NETWORK TRANSFORMER

(71) Applicant: TAI-TECH ADVANCED ELECTRONICS CO., LTD., Taoyuan City (TW)

(72) Inventors: Ming-Yen Hsieh, Taoyuan City (TW); Pao-Lin Shen, Taoyuan City (TW); Hsiang-Chung Yang, Taoyuan City (TW); Wei-Hsuan Lo, Taoyuan City (TW)

(21) Appl. No.: 18/126,983

(22) Filed: Mar. 27, 2023

(51) Int. Cl. H01F 27/29; H01F 27/28; H05K 1/16

(52) U.S. Cl. CPC H01F 27/292; H01F 27/2804; H05K 1/165; H05K 2201/086

(57) ABSTRACT

The inductor-type network transformer includes a circuit board, at least one transformer member mounted to the circuit board, at least one peripheral element mounted to the circuit board to a side of the transformer member, and a casing configured on the circuit board completely covering the at least one transformer member, and the at least one peripheral element. The present invention configures at least a transformer member and at least a peripheral element on a circuit board through Surface Mount Technology (SMT), which are all entirely covered by a casing, thereby avoiding the conventional manual process's complexity and inconvenience, and enhancing production cost and efficiency. As the peripheral elements, such as Transient Voltage Suppressor (TVS) diodes, are also integrated inside the casing, the network transformer is more robust to electrical shocks. The integration of the peripheral elements inside the casing also helps to product miniaturization.

### BACKGROUND OF THE INVENTION

### (a) Technical Field of the Invention

The present invention is generally related to network transformers, and more particular to an inductor-type network transformer.

### (b) Description of the Prior Art

Network transformers, also known as network isolation transformers, are for impedance matching and anomaly isolation. For example, when impedance is not compatible between two computers or network devices connected by a network cable, the issue may be resolved using a network transformer. In an Ethernet network, a network transformer is conventionally positioned between a Port Physical Layer (PHY) chip and a RJ45 connector. The network transformer may boost signal for transmission over a longer distance, in addition to isolating the PHY chip from outside interference. Together with Transient Voltage Suppressor (TVS) diode to prevent spike from lightning strike, the network transformer may also provide enhanced robustness against lightning.

Conventional network transformers, based on the presence of capacitors inside, can be categorized into inductor-type and capacitor-type network transformers. Based on appearance, there are modular network transformers or element-based network transformers. For modular, inductor-type network transformers, elements such as transformers, common-mode filters are configured on a same circuit board and covered by a casing, appearing as a single module. For modular, capacitor-type network transformers, elements such as transformers, common-mode filters, and capacitors are configured on a same circuit board and covered by a casing, appearing as a single module.

A conventional network transformer is disclosed by R. O. C. Taiwan Patent No. M325594. As illustrated in the disclosure's FIG. 1, a coil-type transformer member (including elements such as transformer and common-mode filter, etc.) is configured on a circuit board. Lead wires of the transformer member are then manually bound to the pins. Another conventional network transformer is disclosed by R. O. C. Taiwan Patent No. 1263421. According to the disclosure's FIG. 1, after the lead wires are bound, they are manually welded to internal terminals of the pins and, finally, the casing is placed on the circuit board to cover the transformer member.

The manufacturing of the conventional network transformers is labor intensive, time consuming, and can't be automated using Surface Mount Technology (SMT). Generally, a SMT process involves, firstly, applying solder paste onto a circuit board at where electronic components are to be configured using solder paste printing. Then, electronic components are disposed on the circuit board through a pick and placement machine. Finally, the circuit board is heated in a reflow oven to melt the solder paste so as to fix the electronic components to the circuit board. In contrast, in a manual process, a transformer member is first welded to the circuit board manually. The casing is then placed over the circuit board to cover the transformer member. Finally, peripheral elements are configured on the circuit board outside the casing.

As shown in FIG. 1, a conventional network transformer includes transformers 120 and common-mode filters 130 (both denoted using equivalent circuits) inside a casing 110 (denoted by dashed line). PHY terminals A are connected to ground through capacitors 210. RJ terminals B are connected to ground via resistors 220 and a high-voltage capacitor 230. As shown in FIG. 2, another conventional network transformer includes transformers 120 and common-mode filters 130 (both denoted using equivalent circuits) inside a casing 110 (denoted by dashed line). PHY terminals A are connected to ground through capacitors 210. PHY differential lines are also connected to TVS diodes 240. RJ terminals B are connected to ground via resistors 220 and a high-voltage capacitor 230. Capacitors 210, resistors 220, high-voltage capacitor 230, and TVS diodes 240 are all disposed outside the casing 110.

The conventional manufacturing process has a number of drawbacks. Firstly, the dimension of the circuit board should be greater than the casing so as to dispose peripheral elements like the capacitors, resistors, high-voltage capacitor, or TVS diodes, which implies that miniaturization would be difficult. Secondly, the manual process involved means low efficiency, high error rate, and high cost.

### SUMMARY OF THE INVENTION

To obviate the prior art's shortcomings, the present invention teaches an inductor-type network transformer which includes a circuit board, at least one transformer member mounted to the circuit board, at least one peripheral element mounted to the circuit board to a side of the transformer member, and a casing configured on the circuit board completely covering the at least one transformer member, and the at least one peripheral element.

Specifically, the at least one transformer member includes a chip-type transformer.

Specifically, the at least one transformer member includes a common-mode filter.

Specifically, the at least one peripheral element may be a capacitor, a resistor, a high-voltage capacitor, or a Transient Voltage Suppressor (TVS) diode.

The present invention configures at least a transformer member and at least a peripheral element on a circuit board through Surface Mount Technology (SMT), which are all entirely covered by a casing, thereby avoiding the conventional manual process's complexity and inconvenience, and enhancing production cost and efficiency. As the peripheral elements, such as Transient Voltage Suppressor (TVS) diodes, are also integrated inside the casing, the network transformer is more robust to electrical shocks. The integration of the peripheral elements inside the casing also helps product miniaturization.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic diagram showing a conventional network transformer.

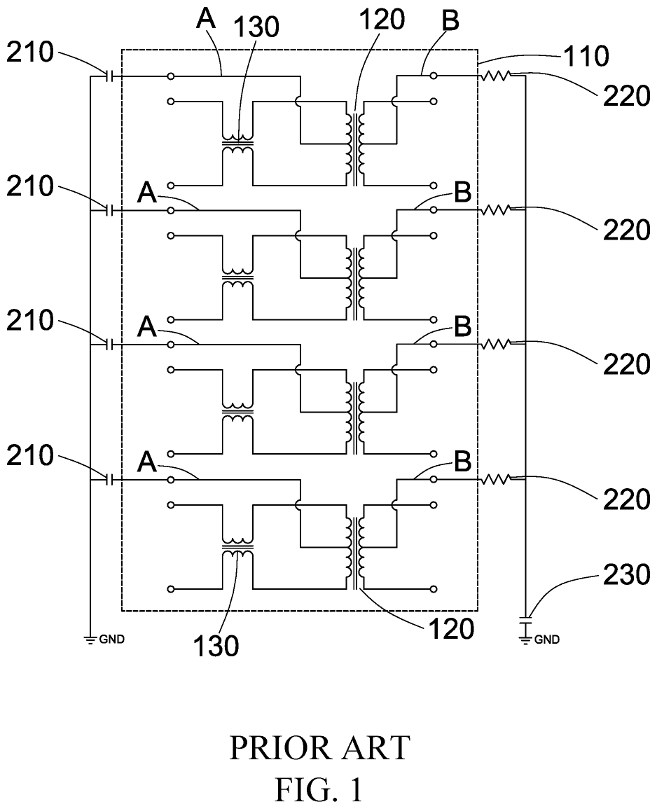

FIG. 2 is a schematic diagram showing another conventional network transformer.

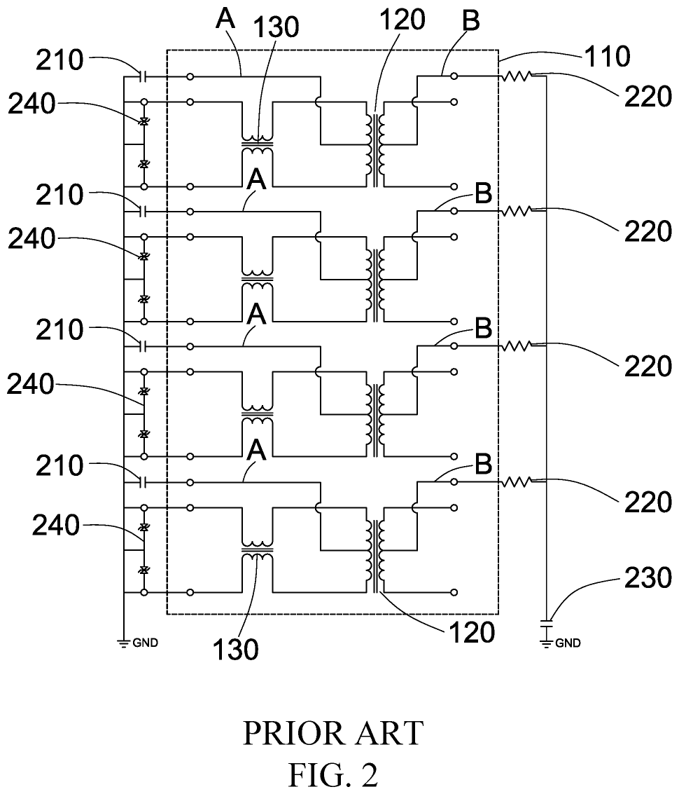

FIG. 3 is a perspective diagram showing a network transformer according to the present invention.

FIG. 4 is a perspective diagram showing the inside of a network transformer according to the present invention.

FIG. 5 is a schematic diagram showing a network transformer according to a first embodiment of the present invention.

FIG. 6 is a schematic diagram showing a network transformer according to a second embodiment of the present invention.

FIG. 7 is a schematic diagram showing a network transformer according to a third embodiment of the present invention.

FIG. 8 is a schematic diagram showing a network transformer according to a fourth embodiment of the present invention.

FIG. 9 is a schematic diagram showing a network transformer according to a fifth embodiment of the present invention.

FIG. 10 is a schematic diagram showing a network transformer according to a sixth embodiment of the present invention.

FIG. 11 is a schematic diagram showing a network transformer according to a seventh embodiment of the present invention.

FIG. 12 is a schematic diagram showing a network transformer according to an eighth embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

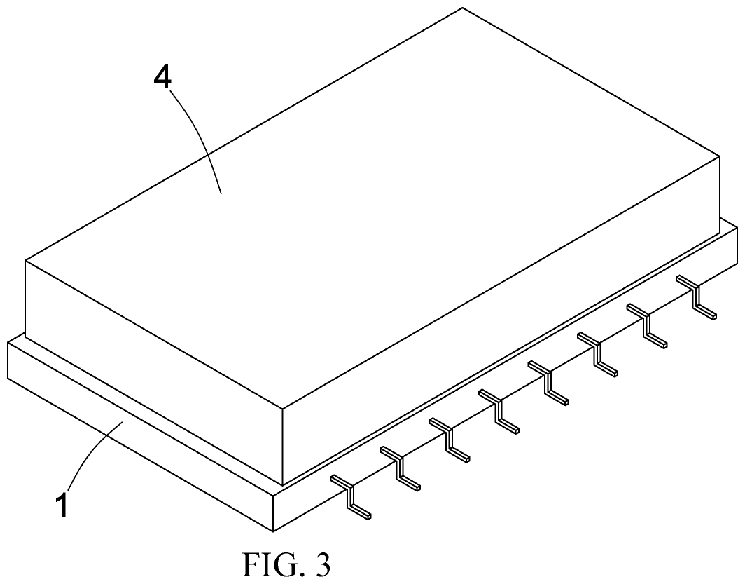

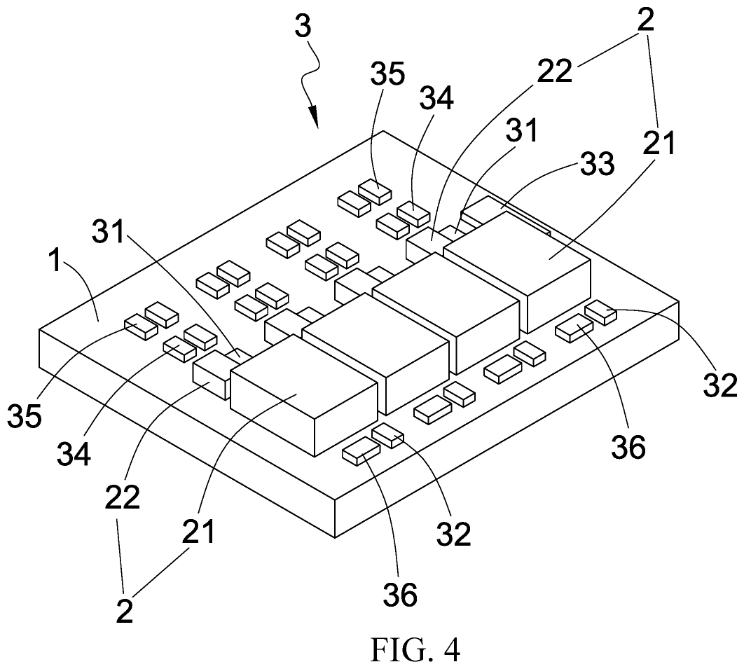

As shown in FIGS. 3 and 4, a network transformer according to the present invention includes a circuit board 1, at least a transformer member 2, at least a peripheral element 3, and a casing 4.

The circuit board 1, depending on product or design demand, may be a single-layer board, dual-layer board, or multi-layer board. When the circuit board 1 is a dual-layer or multi-layer board, there are vias connecting layouts (including contracts) on different layers. The details are well-known to persons skilled in the related arts and, therefore, are omitted here.

Each transformer member 2 includes a chip-type transformer 21 and a common-mode filter 22. Each transformer member 2 is mounted on the circuit board 1 through means such as Surface Mount Technology (SMT).

Each peripheral element 3 may be a capacitor 31, a resistor 32, a high-voltage capacitor 33, a Transient Voltage Suppressor (TVS) diode, or an overcurrent or overvoltage protection element, but the present invention is not limited as such.

The casing 4 is configured on the circuit board 1, and completely covers the transformer members 2 and the peripheral elements 3. The casing 4 has a cubic or rectangular three-dimensional shape with an open bottom side and a hollow inside for accommodating the transformer members 2 and the peripheral elements 3.

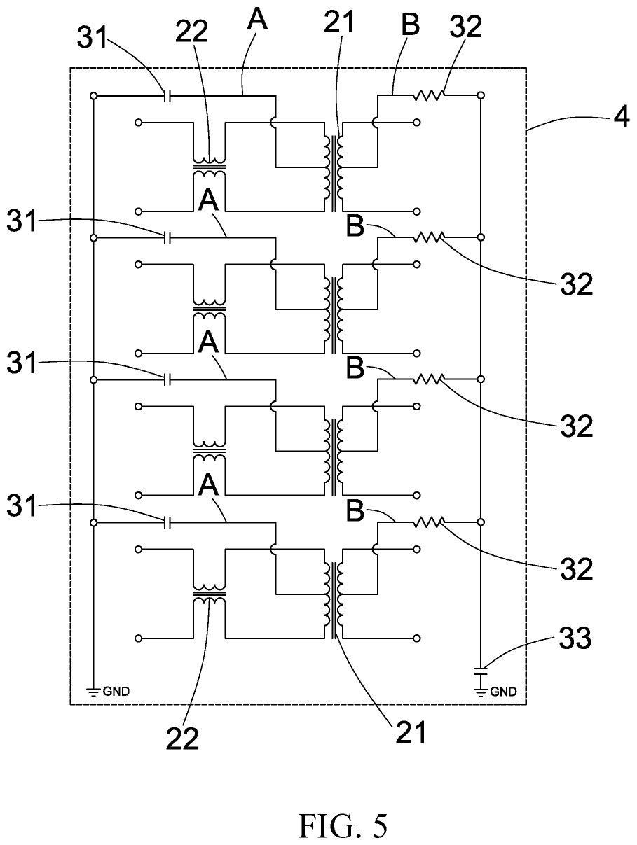

FIGS. 5 to 12 respectively illustrate various embodiments of the present invention, which are described as follows.

### First Embodiment

As shown in FIG. 5, all configured inside the casing 4 (denoted by dashed line), there are transformers 21, common-mode filters 22, capacitors 31, resistors 32, and a high-voltage capacitor 33. PHY terminals A are connected to ground via the capacitors 31. RJ terminals B are connected to ground via the resistors 32 and the high-voltage capacitor 33. The resistors 32 and the high-voltage capacitor 33 jointly form a Bob Smith circuit to achieve signal impedance matching and interference suppression. In short, a lead wire is connected from a transformer 21's primary side coil (i.e., PHY terminal A) to a capacitor 31 and then to ground. It is called PHY terminal due to its proximity to a PHY chip (not shown). Similarly, another lead wire is connected from a transformer 21's secondary side coil (i.e., RJ terminal B) to a resistor 32 and the high-voltage capacitor 33 and then to ground. It is called RJ terminal due to its proximity a RJ45 connector (not shown).

### Second Embodiment

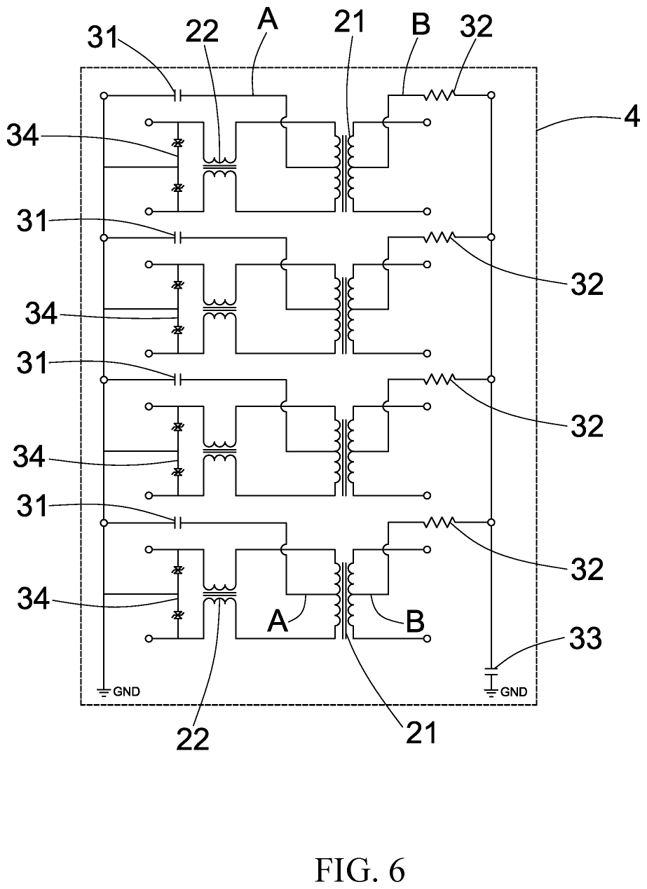

As shown in FIG. 6, all configured inside the casing 4 (denoted by dashed line), there are transformers 21, common-mode filters 22, capacitors 31, resistors 32, a high-voltage capacitor 33, and TVS diodes 34. PHY terminals A are connected to ground via the capacitors 31. PHY differential lines are connected to ground via the TVS diodes 34. RJ terminals B are connected to ground via the resistors 32 and the high-voltage capacitor 33. The differential lines are employed to guard against interference, and TVS diodes 34 are to prevent spikes resulted from lighting strike.

### Third Embodiment

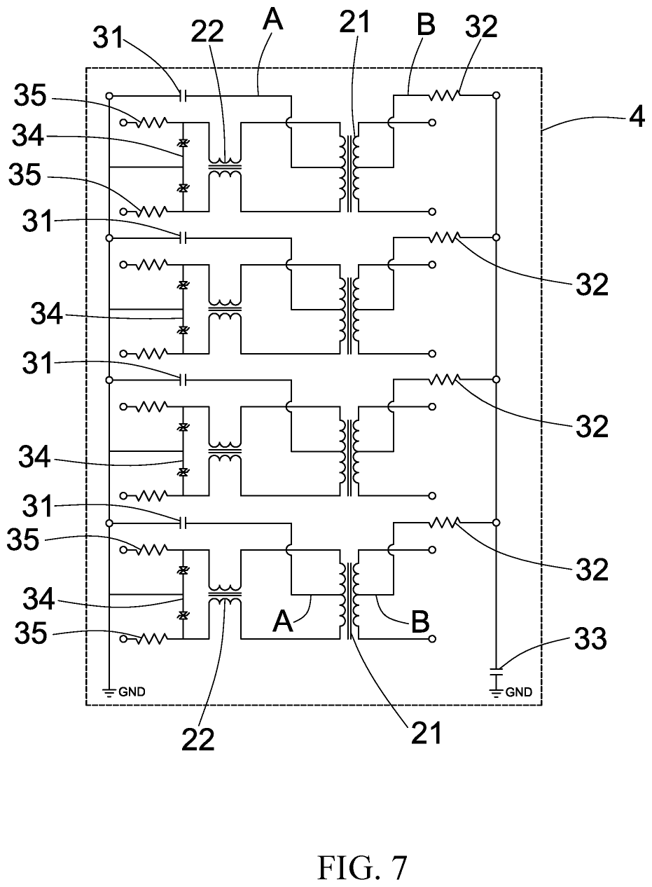

As shown in FIG. 7, all configured inside the casing 4 (denoted by dashed line), there are transformers 21, common-mode filters 22, capacitors 31, resistors 32, a high-voltage capacitor 33, TVS diodes 34, and current limiting resistors 35. PHY terminals A are connected to ground via the capacitors 31. PHY differential lines are connected to ground via the TVS diodes 34. PHY differential lines are also connected to the current limiting resistors 35. RJ terminals B are connected to ground via the resistors 32 and the high-voltage capacitor 33.

### Fourth Embodiment

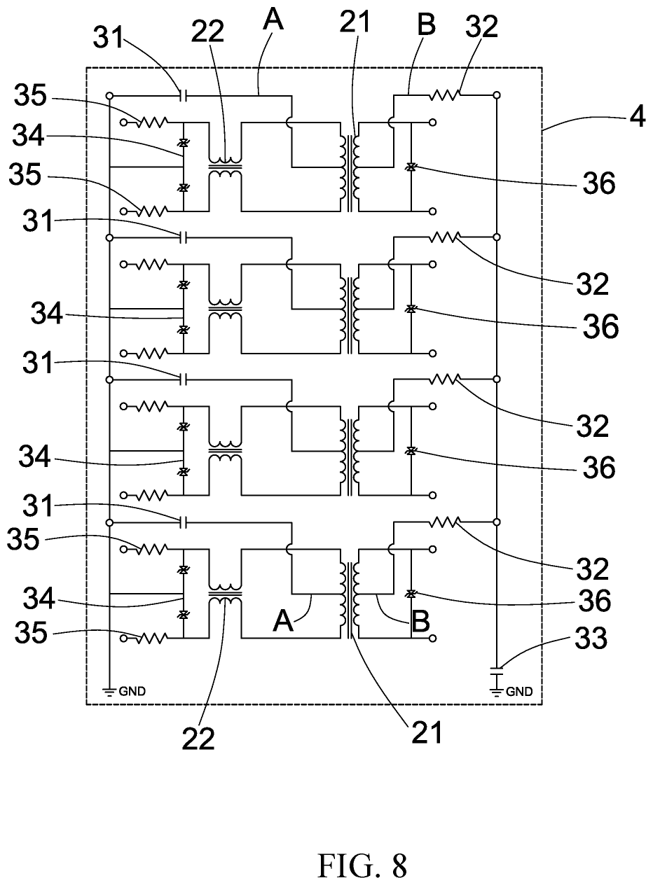

As shown in FIG. 8, all configured inside the casing 4 (denoted by dashed line), there are transformers 21, common-mode filters 22, capacitors 31, resistors 32, a high-voltage capacitor 33, TVS diodes 34, 36, and current limiting resistors 35. PHY terminals A are connected to ground via the capacitors 31. PHY differential lines are connected to ground via the TVS diodes 34. PHY differential lines are also connected to the current limiting resistors 35. RJ terminals B are connected to ground via the resistors 32 and the high-voltage capacitor 33. RJ differential lines are also connected to the TVS diodes 36.

### Fifth Embodiment

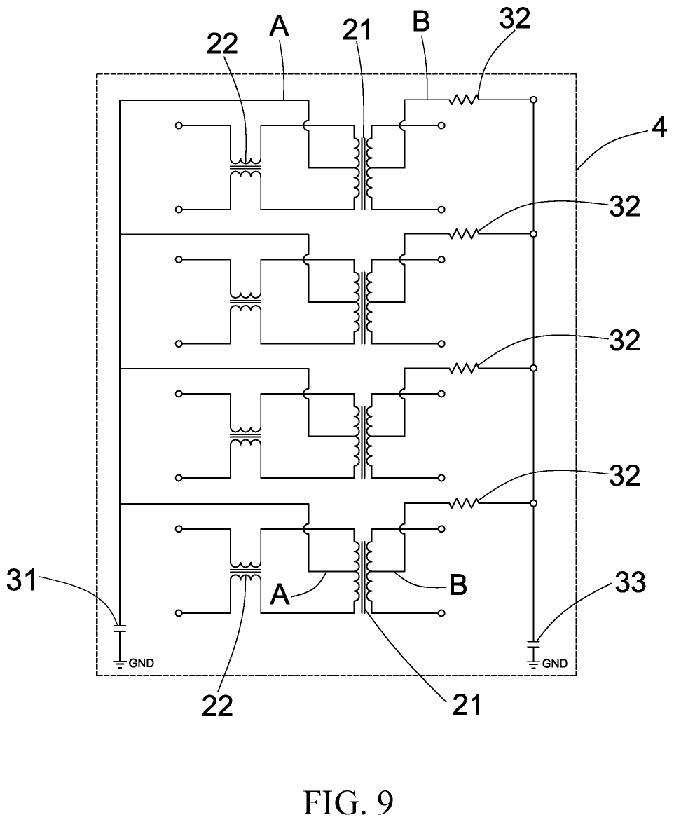

As shown in FIG. 9, all configured inside the casing 4 (denoted by dashed line), there are transformers 21, common-mode filters 22, a capacitor 31, resistors 32, and a high-voltage capacitor 33. PHY terminals A are connected to ground via the capacitor 31. RJ terminals B are connected to ground via the resistors 32 and the high-voltage capacitor 33. The present embodiment is an extension of the first embodiment whose multiple capacitors 31 are reduced to a single, shared capacitor 31.

### Sixth Embodiment

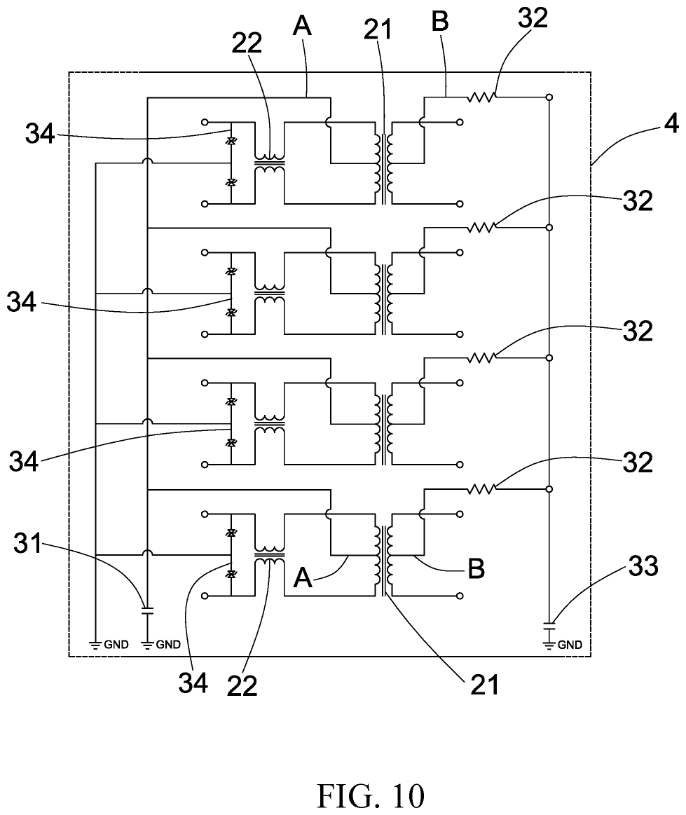

As shown in FIG. 10, all configured inside the casing 4 (denoted by dashed line), there are transformers 21, common-mode filters 22, a capacitor 31, resistors 32, a high-voltage capacitor 33, and TVS diodes 34. PHY terminals A are connected to ground via the shared capacitor 31. PHY differential lines are connected to ground via the TVS diodes 34. RJ terminals B are connected to ground via the resistors 32 and the high-voltage capacitor 33.

### Seventh Embodiment

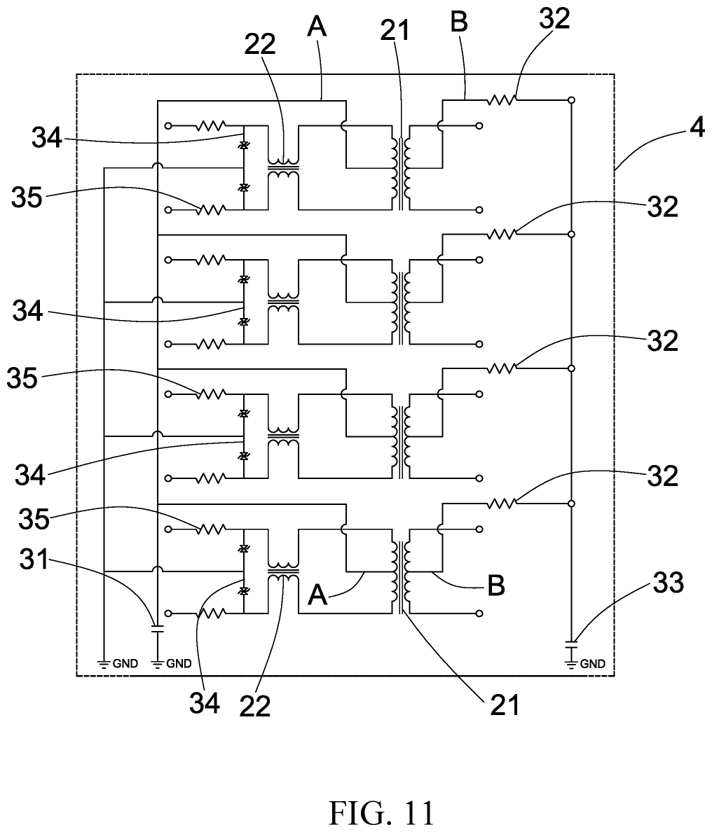

As shown in FIG. 11, all configured inside the casing 4 (denoted by dashed line), there are transformers 21, common-mode filters 22, a capacitor 31, resistors 32, a high-voltage capacitor 33, TVS diodes 34, and current limiting resistors 35. PHY terminals A are connected to ground via the shared capacitor 31. PHY differential lines are connected to ground via the TVS diodes 34. PHY differential lines are also connected to the current limiting resistors 35. RJ terminals B are connected to ground via the resistors 32 and the high-voltage capacitor 33.

### Eighth Embodiment

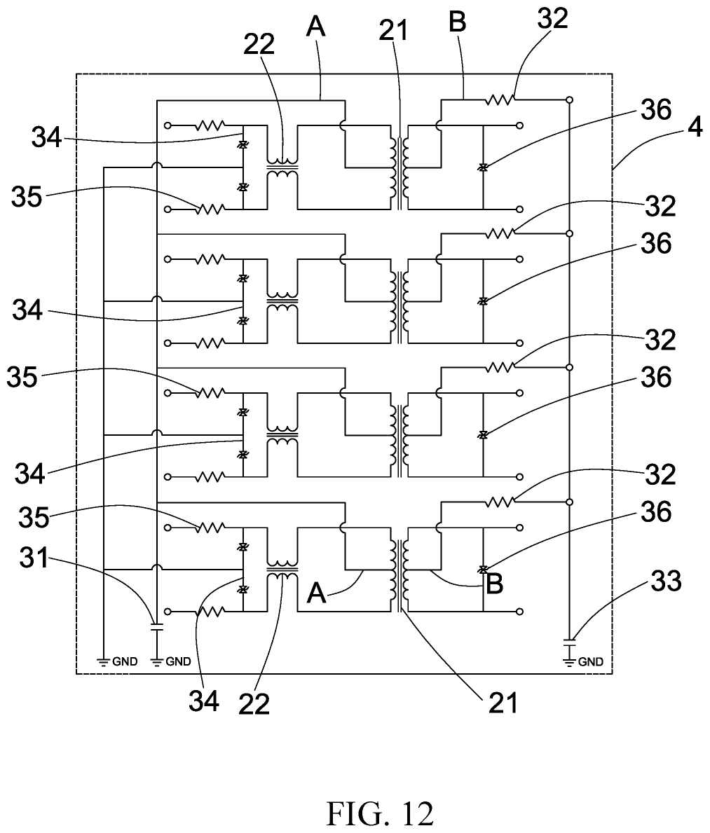

As shown in FIG. 12, all configured inside the casing 4 (denoted by dashed line), there are transformers 21, common-mode filters 22, a capacitor 31, resistors 32, a high-voltage capacitor 33, TVS diodes 34, 36, and current limiting resistors 35. PHY terminals A are connected to ground via the shared capacitor 31. PHY differential lines are connected to ground via the TVS diodes 34. PHY differential lines are also connected to the current limiting resistors 35. RJ terminals B are connected to ground via the resistors 32 and the high-voltage capacitor 33. RJ differential lines are also connected to the TVS diodes 36.

As described, the present invention configures at least a transformer member 2 and at least a peripheral element 3 on a circuit board 1 through Surface Mount Technology (SMT), which are all entirely covered by a casing 4, thereby avoiding the conventional manual process's complexity and inconvenience, and enhancing production cost and efficiency. As the peripheral elements 3, such as TVS diodes, are also integrated inside the casing 4, the network transformer is more robust to electrical shocks. The integration of the peripheral elements 3 inside the casing also helps product miniaturization.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I CLAIM:

1. An inductor-type network transformer, comprising:
a circuit board;
at least one transformer member mounted to the circuit board;
at least one peripheral element mounted to the circuit board to a side of the transformer member, and
a casing configured on the circuit board completely covering the at least one transformer member, and the at least one peripheral element.

2. The network transformer according to claim 1, wherein the at least one transformer member comprises a chip-type transformer.

3. The network transformer according to claim 1, wherein the at least one transformer member comprises a common-mode filter.

4. The network transformer according to claim 1, wherein the at least one peripheral element is a capacitor, a resistor, a high-voltage capacitor, or a Transient Voltage Suppressor (TVS) diode.
